(19) United States
(12) Patent Application Publication
(10) Pub. No.: US 2011/0259738 A1
(43) Pub. Date: Oct. 27, 2011

(54) MAGNETRON SPUTTERING DEVICE

(75) Inventor: SHAO-KAI PEI, Tu-Cheng (TW)

(73) Assignee: HON HAI PRECISION INDUSTRY CO., LTD., Tu-Cheng (TW)

(21) Appl. No.: 12/869,705

(22) Filed: Aug. 26, 2010

(30) Foreign Application Priority Data
Apr. 21, 2010 (TW) 99112448

(51) Int. Cl. C23C 14/35

(52) U.S. Cl. 204/298.09; 204/298.16

(57) ABSTRACT

A magnetron sputtering device includes a holding compartment, a target assembly, a supporting base, and a rotation module. The holding compartment is divided to a reactive chamber and a receiving chamber. The target assembly includes two cooling plates, two magnetic units, and a target. The two cooling plates define a magnetron room communicating with the receiving chamber. The two magnetic units are suspended in the magnetron room. The target is attached on the cooling plate under the magnetic units. The supporting base is for supporting work-pieces. The rotation module is received in the receiving chamber, and jointed to the two magnetic units. The rotation module drives the magnetic units to spin about a central axis thereof and move back and forth along a direction lengthwise of the magnetic unit.

### BACKGROUND

1. Technical Field

The present disclosure relates to magnetron sputtering devices and, particularly, relates to a magnetron sputtering device having a movable magnetic unit.

2. Description of Related Art

A typical magnetron sputtering device includes a target assembly and an immovable magnet received in the target assembly. Magnetic fields of the immovable magnet are superimposed and produce a superimposed magnetic field which conducts magnetic density surrounding the target assembly uniformly. As such, more atoms are accelerated to reach some high magnetic density portions of the target assembly, but less reaches to other low magnetic density portions. Therefore, the high magnetic density portions of the target assembly may have a higher consumption rate while the other low magnetic density portions may have a lower consumption rate. The utilization efficiency of the target assembly is low.

Therefore, it is desirable to provide a magnetron sputtering device which can overcome the limitations described above.

### BRIEF DESCRIPTION OF THE DRAWINGS

FIG. 1 is a schematic cross-sectional view of a magnetron sputtering device, according to an exemplary embodiment.

FIG. 2 is a schematic cross-sectional view of a magnetron sputtering device, according to another exemplary embodiment.

### DETAILED DESCRIPTION

Embodiments of the disclosure will now be described in detail, with reference to the accompanying drawings.

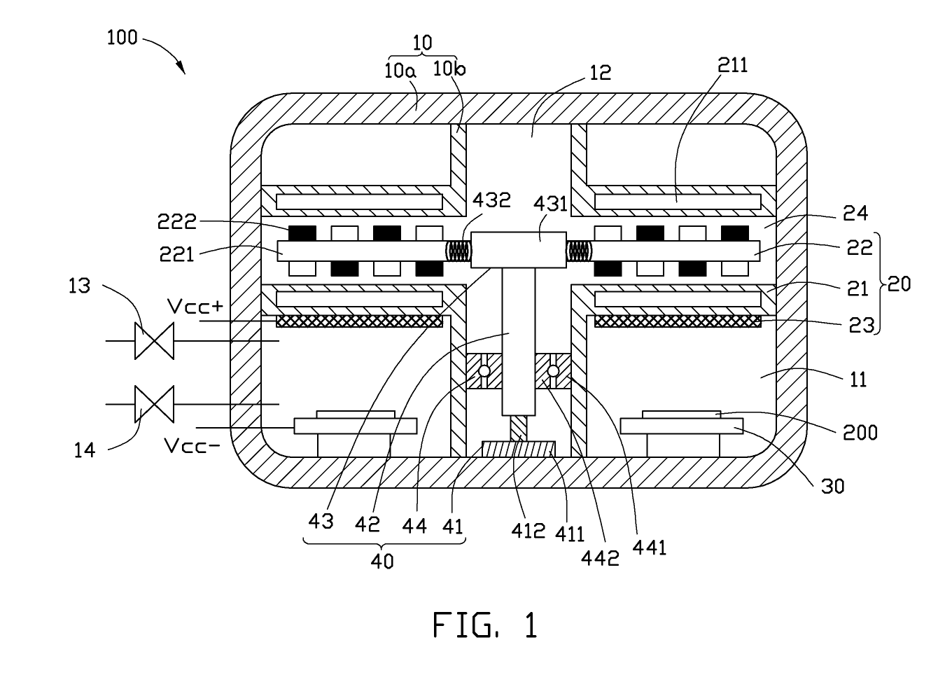

Referring to FIG. 1, a magnetron sputtering device 100, according to an exemplary embodiment, is provided to sputter work-pieces 200. The magnetron sputtering device 100 includes a holding compartment 10, a target assembly 20, a supporting base 30, and a rotation module 40. The target assembly 20, the supporting bases 30, and the rotation module 40 all are received in the holding compartment 10. The work-pieces 200 are respectively supported on the supporting base 30.

The holding compartment 10 includes an outer case 10a and an inner case 10b. The outer case 10a and the inner case 10b are substantially cylindrical in shape and substantially symmetrical about a central axis of the outer case 10a. The inner case 10b is perpendicularly positioned between an upper surface and a lower surface of the outer case 10a. A reactive chamber 11 is defined between the inner case and the outer case and a receiving chamber 12 is defined in the inner case. The reactive chamber 11 surrounds the receiving chamber 12. A gas inlet system 13 and a gas outlet system 14 are respectively equipped on the outer case 10a. The gas inlet system 13 establishes air path between the reactive chamber 11 and a gas source (not shown) for the noble gas in the gas source flowing into the reactive chamber 11 thereby. The gas outlet system 14 conducts excess gas vented from the reactive chamber 11 to a waste gas collection device (not shown).

The target assembly 20 includes two cooling plates 21, two magnetic units 22, and a target 23. The cooling plates 21 are an annular configuration, and positioned parallel between a sidewall of the outer case 10a and the inner case 10b. In this embodiment, the cooling plates 21 are integrative with the inner case 10b. Each cooling plate 21 defines a cooling channel 211 therein where is filled with cooling liquid. A magnetron room 24 is defined between the two cooling plates 21, and communicates with the receiving room 12. Two magnetic units 22 are suspended in the magnetron room 24. Each magnetic unit 22 includes a supporting arm 221 and a number of magnets 222 positioned on the supporting arm 221. The magnets 222 surround the supporting arm 221 with consequent-poles along a direction lengthwise of the supporting arm 221. In this embodiment, the magnets 222 are imbedded in the supporting arm 221. The target 23 is attached on the cooling plate 21 underneath the magnetic units 22 and positioned toward the lower surface of the outer case 10a. A positive voltage is applied to the target 23.

The supporting base 30 is annular configuration and disposed on the lower surface of the reactive chamber 11. The inner diameter of the supporting base 30 is greater than the outer diameter of the inner case 10b. The outer diameter of the supporting base 30 is shorter than the inner diameter of the outer case 10a. The work-pieces 200 are supported on an upper surface of the supporting base 30. A negative voltage is applied to the supporting base 30.

The rotation module 40 is received in the receiving chamber 12. The rotation module 40 includes a driving rotator 41, a transmission rod 42, a liner rotator 43, and a bearing 44. The driving rotator 41 includes a first stator 411 and a first rotor 412. The first stator 411 is disposed on the lower surface of the outer case 10a. The first rotor 412 is coupled to one end of the transmission rod 42. The liner rotator 43 includes a second stator 431 and a second rotor 432 engaged to the second stator 431. The second stator 431 is perpendicularly connected to the opposite end of the transmission rod 42. Two supporting arms 221 are respectively jointed to two corresponding ends of the second rotor 432. The bearing 44 is an angular contact ball bearing consisting of an outer ring 441 and an inner ring 442 rotatably engaged in the outer ring 441. The outer ring 441 is received in the receiving chamber 12 and positioned on the inner case 10b. The transmission rod 42 is interferentially positioned in the inner ring 442.

In operation, the driving actuator 41 rotates the magnetic units 22 about a center axis of the transmission rod 42. The liner rotator 43 rotates the magnetic units 22 about a center axis of the supporting arm 221, as such driving the magnetic units 22 back and forth along the direction lengthwise of the supporting arm 221. As a result, uniformity of the magnetic density of the magnetic units 22 around the outer surface of the target 30 is improved.

During sputtering, the reactive chamber 11 is under a vacuum by the outlet system 14 until the air pressure in the reactive chamber 11 reaches about 1.3×10⁻³ Pa. Then a noble gas, such as argon (Ar), is filled in the reactive chamber 11 by the gas inlet system 13. The noble gas is excited by electrons generated from the glow discharge, and a number of plasmas are subsequently generated. The glow discharge is generated by the application of a voltage in the range from 100 V (volts) to several kV (kilovolts) through the residual gas at low pressure. The target 23 is bombarded by the plasma under force of the voltage difference applied, and generates a multiplicity of target atoms. The target atoms are coated on the work-pieces 200.

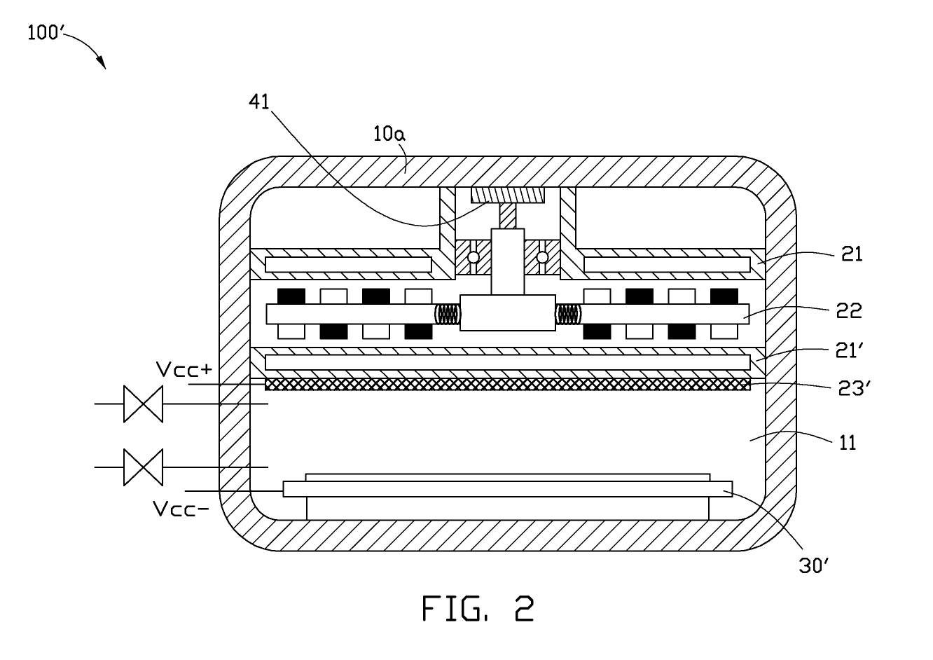

Referring to FIG. 2, a magnetron sputtering device 100′ according to another exemplary embodiment is similar to the magnetron sputtering device 100, except that the magnetron sputtering device 100′ includes a cooling plate 21′, a target 23′, and a supporting base 30′. The cooling plate 21′ is circular configuration and faces to the lower surface of the outer case 10a. The cooling plate 21′ is positioned between the sidewall of the outer case 10a. The reactive chamber 11 is defined by the circular cooling plate 21′, the sidewall of the outer case 10a, and the lower surface of the outer case 10a. The supporting base 30′ is circular configuration and disposed on the lower surface of the outer case 10a. The cooling plate 21′ and the supporting base 30′ are opposite to each other. The driving rotator 41 is disposed on the upper surface of the outer case 10a. The magnetic units 22 are suspended between the circular cooling plate 21′ and the annular cooling plate 21. The target 23′ is positioned on the cooling plate 21′ and faces the supporting base 30′.

Particular embodiments and methods are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A magnetron sputtering device for coating work-pieces, comprising:
a holding compartment comprising an outer case and an inner case positioned in the outer case, a reactive chamber being defined between the inner case and the outer case, a receiving chamber being defined in the inner case;
a target assembly comprising two cooling plates, two magnetic units, and a target, the two cooling plates being positioned between the outer case and the inner case and defining a magnetron room communicating with the receiving chamber, the two magnetic units being suspended in the magnetron room, the target being attached on the cooling plate under the two magnetic units;
a supporting base positioned on a lower surface of the outer case and facing the target for supporting the work-pieces thereon; and
a rotation module received in the receiving chamber, and jointed to the two magnetic units; the rotation module being configured to drive the magnetic units to spin about a central axis thereof and move back and forth along a direction lengthwise of the magnetic unit.

2. The magnetron sputtering device of claim 1, wherein the rotation module comprises a driving rotator and a liner rotator, the driving rotator comprises a first stator and a first rotor, the liner rotator comprises a second stator and a second rotor, the first stator is positioned on the lower surface of the inner case, the first rotor is perpendicularly connected to the second stator, the second rotor is engaged with the second stator and coupled to the two magnetic units.

3. The magnetron sputtering device of claim 2, wherein the rotation module further comprises a transmission rod, one end of the transmission rod is coaxially coupled to the first rotor, the other opposite end is perpendicularly connected to the second stator.

4. The magnetron sputtering device of claim 3, wherein the rotation module further comprises a bearing, the bearing comprises an outer ring and an inner ring, the outer ring is received in the receiving chamber and positioned on the inner case, the transmission rod is interferentially positioned in the inner ring.

5. The magnetron sputtering device of claim 1, wherein a positive voltage is applied to the target and a negative voltage is applied to the supporting base.

6. The magnetron sputtering device of claim 1, wherein each magnetic unit comprises a supporting arm and a plurality of magnets positioned on the supporting arm, the magnets surround the supporting arm with consequent-poles along a direction lengthwise of the supporting arm.

7. The magnetron sputtering device of claim 1, wherein the outer case and the inner case are substantially cylindrical and substantially symmetrical about a central axis of the outer case.

8. The magnetron sputtering device of claim 7, wherein the cooling plates are annular shaped and positioned between the inner case and a sidewall of the outer case.

9. The magnetron sputtering device of claim 7, wherein the supporting base is annular shaped and surrounds the inner case.

10. The magnetron sputtering device of claim 7, wherein the target is annular shaped and surrounds the inner case.

11. The magnetron sputtering device of claim 1, wherein each cooling plate defines a cooling channel therein where is filled with a cooling liquid.

12. A magnetron sputtering device for coating work-pieces, comprising:
a holding compartment comprising an outer case and an inner case positioned in the outer case, a receiving chamber being defined in the inner case;
a target assembly comprising a first and a second cooling plates, two magnetic units, and a target, the first cooling plate being positioned between the inner case and a sidewall of the outer case, the second cooling plate being positioned between the sidewall of the outer case, the two cooling plates defining a magnetron room communicating with the receiving chamber, the two magnetic units being suspended in the magnetron room, a reactive chamber being defined by the second cooling plate, the sidewall of the outer case and a lower surface of the outer case, the target being attached on the second cooling plate and received in the reactive room;
a supporting base positioned on the lower surface of the outer case and facing the target for supporting the work-pieces; and
a rotation module received in the receiving chamber and positioned on an upper surface of the outer case, the rotation module being connected to the two magnetic units, the rotation module being configured to drive the magnetic units to rotate with respect to a central axis thereof and move back and forth along a direction lengthwise of the magnetic unit.

13. The magnetron sputtering device of claim 12, wherein the rotation module comprises a driving rotator and a liner rotator, the driving rotator comprises a first stator and a first rotor, the liner rotator comprises a second stator and a second rotor, the first stator is positioned on the upper surface of the inner case, the first rotor is perpendicularly connected to the second stator, the second rotor is engaged with the second stator and coupled to the two magnetic units.

14. The magnetron sputtering device of claim 13, wherein the rotation module further comprises a transmission rod, one end of the transmission rod is coaxially coupled to the first rotor, the other opposite end is perpendicularly connected to the second stator.

15. The magnetron sputtering device of claim 14, wherein the rotation module further comprises a bearing, the bearing comprises an outer ring and an inner ring, the outer ring is received in the receiving chamber and positioned on the inner case, the transmission rod is interferentially positioned in the inner ring.

16. The magnetron sputtering device of claim 12, wherein the outer case and the inner case are substantially cylindrical and substantially symmetrical about a central axis of the outer case.

17. The magnetron sputtering device of claim 16, wherein the first cooling plate is annular shaped, the second cooling plate is circular shaped.

18. The magnetron sputtering device of claim 16, wherein the supporting base is circular shaped.

19. The magnetron sputtering device of claim 16, wherein the target is circular shaped.

20. The magnetron sputtering device of claim 12, wherein each magnetic unit comprises a supporting arm and a plurality of magnets positioned on the supporting arm, the magnets surround the supporting arm with consequent-poles along a direction lengthwise of the supporting arm.
